(19) United States
(12) Patent Application Publication
(10) Pub. No.: US 2024/0222259 A1
(43) Pub. Date: Jul. 4, 2024

(54) METHODS, SYSTEMS, APPARATUS, AND ARTICLES OF MANUFACTURE TO PRODUCE INTEGRATED CIRCUIT PACKAGES HAVING SILICON NITRIDE ADHESION PROMOTERS

(71) Applicant: Intel Corporation, Santa Clara, CA (US)

(72) Inventors: Haobo Chen, Chandler, AZ (US); Bohan Shan, Chandler, AZ (US); Xiyu Hu, Phoenix, AZ (US); Rhonda Jack, Mesa, AZ (US); Catherine Mau, Phoenix, AZ (US); Hongxia Feng, Chandler, AZ (US); Xiao Liu, Chandler, AZ (US); Wei Wei, Chandler, AZ (US); Srinivas Pietambaram, Chandler, AZ (US); Gang Duan, Chandler, AZ (US); Xiaoying Guo, Chandler, AZ (US); Dingying Xu, Chandler, AZ (US); Kyle Arrington, Gilbert, AZ (US); Ziyin Lin, Chandler, AZ (US); Hiroki Tanaka, Gilbert, AZ (US); Leonel Arana, Phoenix, AZ (US)

(21) Appl. No.: 18/147,535

(22) Filed: Dec. 28, 2022

(51) Int. Cl. H01L 23/498; H01L 21/48; H01L 23/29; H01L 23/31

(52) U.S. Cl. CPC H01L 23/49894; H01L 21/481; H01L 23/291; H01L 23/3192; H01L 24/16

(57) ABSTRACT

Methods, systems, apparatus, and articles of manufacture to produce integrated circuit (IC) packages having silicon nitride adhesion promoters are disclosed. An example IC package disclosed herein includes a metal layer on a substrate, a layer on the metal layer, the layer including silicon and nitrogen, and solder resist on the layer.

### FIELD OF THE DISCLOSURE

This disclosure relates generally to integrated circuit packages and, more particularly, to methods, systems, apparatus, and articles of manufacture to produce integrated circuit packages having silicon nitride adhesion promoters.

### BACKGROUND

In many electronic devices, integrated circuit (IC) chips and/or semiconductor dies are connected to larger circuit boards such as motherboards and/or other types of printed circuit boards (PCBs) via a package substrate. In some electronic devices, solder resist (e.g., solder mask) is provided on one or more areas along a surface of the package substrate and/or the circuit board to protect the areas from application of solder. Further, the solder resist may protect the areas from environmental effects (e.g., dust, heat, moisture, etc.).

### BRIEF DESCRIPTION OF THE DRAWINGS

FIG. 1 illustrates an example integrated circuit (IC) package on a printed circuit board.

FIG. 2 is a cross-sectional view of a solder resist layer coupled to a first substrate using direct bonding.

FIG. 3 illustrates a portion of an example substrate including an example adhesive layer to couple example solder resist to the substrate.

FIG. 4 illustrates the portion of the example substrate and the example solder resist of FIG. 3 after etching of the adhesive layer.

FIG. 5 illustrates the example solder resist of FIGS. 3 and/or 4, where the solder resist includes a second example opening.

FIG. 6 illustrates the example solder resist including the second example opening of FIG. 5 after etching of the adhesive layer.

FIG. 7 is a flowchart representative of an example method of manufacturing the example substrate including the example solder resist having the second example opening of FIGS. 5 and/or 6.

FIG. 8 is a top view of a wafer including dies that may be included in an IC package constructed in accordance with teachings disclosed herein.

FIG. 9 is a cross-sectional side view of an IC device that may be included in an IC package constructed in accordance with teachings disclosed herein.

FIG. 10 is a cross-sectional side view of an IC package that may include an example adhesive layer, in accordance with various examples.

FIG. 11 is a cross-sectional side view of an IC device assembly that may include an IC package constructed in accordance with teachings disclosed herein.

FIG. 12 is a block diagram of an example electrical device that may include an IC package constructed in accordance with teachings disclosed herein.

In general, the same reference numbers will be used throughout the drawing(s) and accompanying written description to refer to the same or like parts. The figures are not to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of a semiconductor device, “above” is not with reference to Earth, but instead is with reference to a bulk region of a base semiconductor substrate (e.g., a semiconductor wafer) on which components of an integrated circuit are formed. Specifically, as used herein, a first component of an integrated circuit is “above” a second component when the first component is farther away from the bulk region of the semiconductor substrate than the second component.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description. As used herein “substantially real time” refers to occurrence in a near instantaneous manner recognizing there may be real world delays for computing time, transmission, etc. Thus, unless otherwise specified, “substantially real time” refers to real time+/−1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

Many electric circuit substrates (e.g., IC package substrates, PCBs, etc.) include traces (e.g., conductive traces) printed and/or provided on a surface of the substrate. In some cases, the traces may be used to electrically couple different locations on the substrate. For instance, electronic components (e.g., IC chips and/or semiconductor devices) can be soldered to the substrate at the different locations, and electrical signals may be transmitted between the electronic components along the traces. In some instances, solder resist (e.g., solder mask) is applied to one or more areas on the surface of the substrate prior to coupling of the electronic components to the substrate. The solder resist prevents application of solder at the one or more areas to prevent formation of unintended electrical connections (e.g., solder bridges) between one or more locations on the substrate. Additionally, the solder resist may be used to protect the traces from damage resulting from corrosion, oxidation, and/or contamination by dust, moisture, etc.

In some cases, solder resist is coupled to the substrate by direct bonding (e.g., without an adhesive layer therebetween). For instance, a surface (e.g., a copper surface) of the substrate may be roughened prior to coating of the surface with solder resist. In some instances, heat and/or pressure is applied to the solder resist to bond the solder resist to the substrate. In some cases, direct bonding of the solder resist to the substrate may result in impurities and/or defects in the solder resist. Further, direct bonding may not be feasible in some IC packages that include an electrolytic surface finish on the substrate.

In some cases, openings are provided in the solder resist at locations at which electrical connections through the solder resist are to be provided. For instance, the openings can be provided by generating a pattern on the solder resist using photolithography, then removing portions of the solder resist corresponding to the pattern. In such cases, the portions of the solder resist can be removed by rinsing the solder resist in a developer (e.g., aqueous developer) that dissolves the portions corresponding to the pattern. Some known developers include sodium carbonate (Na₂CO₃) and/or magnesium sulfate (MgSO₄). The use of such known developers may result in ions (e.g., sodium ions and/or magnesium ions) remaining on a surface of the solder resist and/or the substrate after the development of the openings. Such ions may prevent and/or reduce effectiveness of some etching methods (e.g., dry etching methods using plasma) for subsequent etching of the surface of the substrate. More particularly, such ions can act as masks that prevent the etching of the underlying materials thereby resulting in a rough and/or uneven, surface.

Examples disclosed herein utilize an example silicon nitride adhesive layer to couple solder resist to an example substrate of an example IC package. In examples disclosed herein, one or more example metal layers are provided on a surface of the substrate using electroplating to produce a surface finish on the substrate. In some examples, the metal layers include a nickel layer coupled to the surface of the substrate, a palladium layer coupled to the nickel layer, and a gold layer coupled to the palladium layer. In examples disclosed herein, an example adhesive layer is provided on the metal layers, where the adhesive layer includes silicon nitride. Example solder resist is coupled to the adhesive layer, and a pattern can be defined on the solder resist using photolithography.

Examples disclosed herein provide one or more example openings (e.g., solder resist openings) in the solder resist by exposure of the solder resist to an example Tetramethylammonium hydroxide (TMAH) developer. The molecular formula of TMAH is N(CH3)4⁺OH⁻. In some examples, the TMAH developer produces an opening having a tapered cross-sectional shape with no undercut (no portion of the solder resist opening sidewall is etched into in a manner that defines an overhang in the opening sidewall). In some examples, the opening includes a footer region proximate the adhesive layer, where a cross-sectional width of the opening is smaller at the footer region compared to any other point along the opening (e.g., the footer region protrudes inward relative to the rest of the solder resist opening sidewall). In examples disclosed herein, a portion of the adhesive layer corresponding to a location of the opening can be removed (e.g., using dry etching), such that the opening extends through the solder resist and the adhesive layer to reveal the underlying surface finish (e.g., the metal layers) of the substrate.

Advantageously, using the adhesive layer to couple the solder resist to the metal layers improves effectiveness and/or reliability of bonding between the solder resist and the metal layer (e.g., compared to when direct bonding is used). Further, by using the TMAH developer to produce the openings (e.g., instead of known aqueous developers including sodium carbonate (Na₂CO₃) and/or magnesium sulfate (MgSO₄)), examples disclosed herein produce openings having a tapered cross-sectional shape with no undercut. In some examples, eliminating undercut from the openings reduces a likelihood of flux trapping compared to openings having an undercut. Additionally, examples disclosed herein produce solder resist having a relatively smooth surface (e.g., a surface roughness of less than 120 nanometers) which improves reliability of the solder resist during subsequent etching and/or assembly procedures.

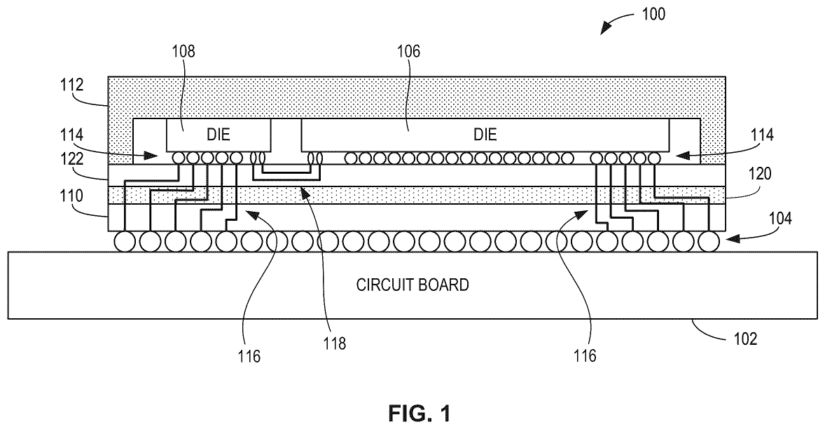

FIG. 1 illustrates an integrated circuit (IC) package 100 electrically coupled to a printed circuit board (PCB) 102. In some examples, the IC package 100 is electrically coupled to the circuit board 102 by first electrical connections 104. The first electrical connections 104 may include pins, pads, bumps, and/or balls to enable the electrical coupling of the IC package 100 to the circuit board 102. In this example, the IC package 100 includes two semiconductor (e.g., silicon) dies 106, 108 that are mounted to a package substrate 110 and enclosed by a package lid or mold compound 112. While the example IC package 100 of FIG. 1 includes two dies 106, 108, in other examples, the IC package 100 may have fewer or more than two dies. As used herein, the terms “dies” and “dice” are interchangeable are refer to the plural of a single die.

As shown in the illustrated example, each of the dies 106, 108 is electrically and mechanically coupled to the package substrate 110 via second electrical connections 114. The second electrical connections 114 may include pins, pads, balls, and/or bumps. The second electrical connections 114 between the dies 106, 108 and the package substrate 110 are sometimes referred to as first level interconnects. By contrast, the first electrical connections 104 between the IC package 100 and the circuit board 102 are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer.

As shown in the illustrated example, the package substrate 110 includes first electrical traces and/or circuit lines (e.g., routing) 116 that electrically connect the first electrical connections 104 to the second electrical connections 114, thereby enabling the electrical coupling of the first and/or second dies 106, 108 with the circuit board 102. Further, in some examples, the package substrate 110 includes second electrical traces and/or circuits (e.g., routing) 118 that electrically connect different ones of the first electrical connections 104 associated with the first and second dies 106, 108, thereby enabling the electrical coupling of the first and second dies 106, 108. In some instances, the package substrate 110 includes a glass core 120 positioned between build-up layers 122 of the package substrate 110.

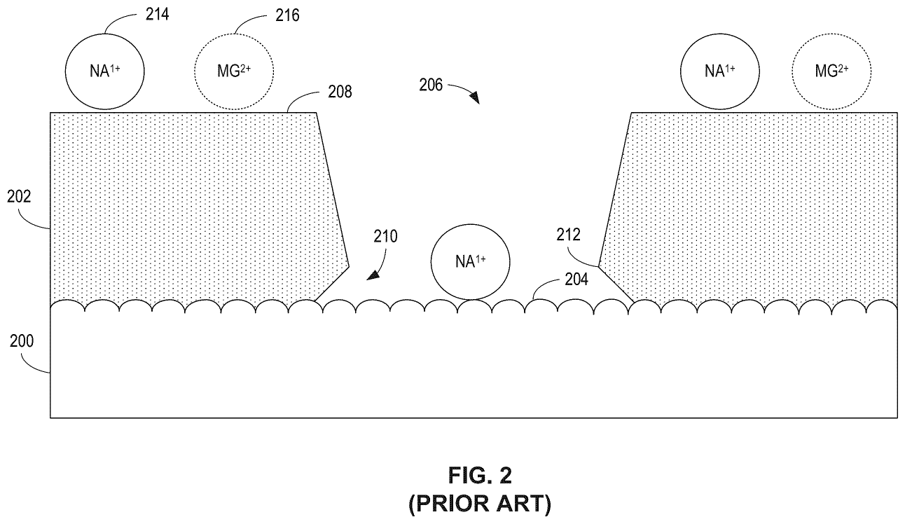

FIG. 2 is a cross-sectional view of a first substrate 200 having solder resist (e.g., solder mask, a solder resist layer) 202 coupled thereto using direct bonding according to known techniques. In some instances, the substrate 200 may be included in the dies 106, 108, the package substrate 110, and/or the PCB 102 of FIG. 1. More particularly, in some instances, the solder resist 202 of FIG. 2 defines an outer surface of any one of the dies 106, 108, the package substrate 110, and/or the PCB 102 along which the electrical connections 104, 114 are distributed as shown in FIG. 1. In FIG. 2, the substrate 200 is an organic substrate with no surface finish (e.g., with no metal plating layer on a surface 204 of the substrate 200). In FIG. 2, the substrate 200 is copper. In some instances, a different material for the substrate 200 may be used instead.

In FIG. 2, the surface 204 is roughened (e.g., nano-roughened) using one or more surface treatments prior to coupling (e.g., bonding) of the solder resist 202 to the surface 204. Such surface treatments may include at least one of sequential bimetallic deposition and chemical etching, or sequential copper oxidation and reduction. In some instances, as a result of roughening, the surface 204 includes high-frequency, low-amplitude surface features. The solder resist 202 is provided (e.g., deposited, laminated) on the surface 204. In some instances, pressure and/or heat is applied to the substrate 200 and/or the solder resist 202 to facilitate bonding between the substrate 200 and the solder resist 202. In some cases, roughening of the surface 204 improves bonding of the solder resist 202 to the substrate 200 (e.g., compared to when the surface 204 is not roughened and/or is relatively smooth).

In FIG. 2, an opening 206 is provided in the solder resist 202 to expose a portion of the substrate 200. In some instances, the opening 206 and the exposed portion of the substrate 200 correspond to a location of an interconnect between the substrate 200 and a separate interfacing substrate (e.g., the second electrical connections 114 between the dies 106, 108 and the package substrate 110 and/or the first electrical connections 104 between the package substrate 110 and the PCB 102). The opening 206 is provided in the solder resist 202 using a photolithography development process. For instance, the solder resist 202 can include a photoresist material, and a pattern can be generated on the solder resist 202 by emitting light toward one or more areas of the solder resist 202 and/or by blocking the light from the one or more areas (e.g., by using a mask). The solder resist 202 is exposed to (e.g., submerged in, rinsed with) an aqueous developer that dissolves portions of the solder resist 202 corresponding to the pattern. In FIG. 2, the opening 206 is generated as a result of the exposure of the solder resist 202 to the aqueous developer, where the opening 206 extends between a top surface 208 of the solder resist 202 and the surface 204 of the substrate 200. In FIG. 2, the aqueous developer includes sodium carbonate (Na₂CO₃) to develop the opening 206 and magnesium sulfate (MgSO₄) to rinse the sodium carbonate from the solder resist 202. In some cases, the use of such aqueous developers may result in the opening 206 having an undercut 210. In particular, a width of the opening 206 decreases from the top surface 208 to a point 212 between the top surface 208 and the surface 204 of the substrate 200, and the width of the opening 206 increases from the point 212 to the surface 204 of the substrate 200. Although the point 212 is shown as a discrete inflection point along the opening 206, in some examples, the transition between the top surface 208 and the surface 204 of the substrate 200 is not discrete, but may be gradual and/or characterized by a curve.

In some cases, the undercut 210 may increase a likelihood of flux trapping in the opening 206. Further, as a result of using the aqueous developer to generate the opening 206, sodium ions 214 and/or magnesium ions 216 may be left on the top surface 208 of the solder resist 202 and/or the surface of the substrate 200. The ions 214, 216 may prevent etching of material below the ions 214, 216 and/or unintentionally increase a surface roughness of the solder resist 202 and/or the substrate 200. Further, when one or more surface finishes (e.g., metal plating layers) are to be included on the surface 204, roughening of the surface 204 may not be feasible and/or may cause damage to the one or more surface finishes.

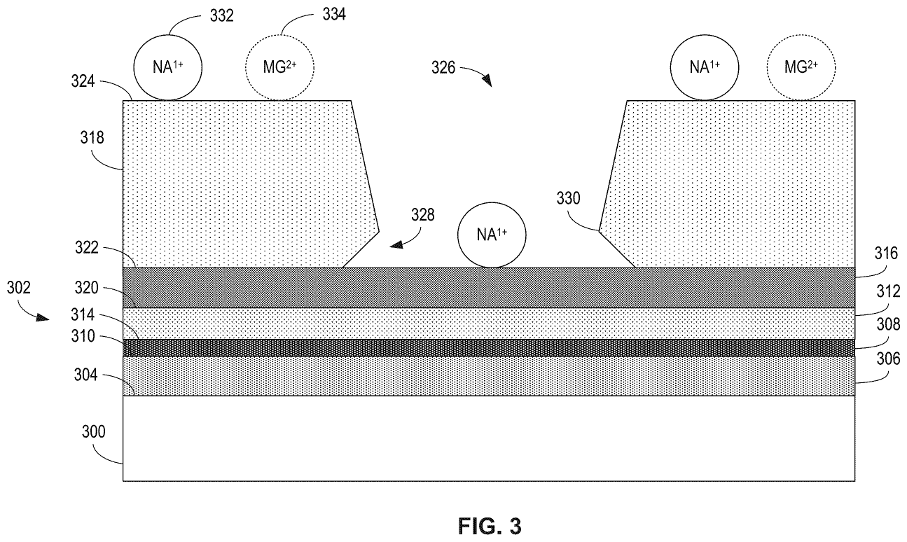

FIG. 3 illustrates an example substrate 300 including one or more surface finish layers (e.g., metal layers, metal plating layers) 302 coupled to a first example surface 304 of the substrate 300 between the substrate 300 and example solder resist (e.g., a solder resist layer) 318. In some examples, the substrate 300 of FIG. 3 may be included in the dies 106, 108, the package substrate 110, and/or the PCB 102 of FIG. 1 (e.g., instead of the substrate 200 of FIG. 2). More particularly, in some examples, the solder resist 318 of FIG. 318 defines an outer surface of any one of the dies 106, 108, the package substrate 110, and/or the PCB 102 along which the electrical connections 104, 114 are distributed as shown in FIG. 1. In the illustrated example of FIG. 3, the substrate 300 includes a first metal material (e.g., copper) and the surface finish layers 302 include one or more second metal materials (e.g., nickel, palladium, and/or gold) different from the first metal material. In some examples, the substrate 300 is couplable (directly or via one or more intermediate layers of material (e.g., build-up layers)) to the glass core 120 of the package substrate 110 of FIG. 1.

In the illustrated example, the surface finish layers 302 include an example nickel layer 306 coupled to the first surface 304 of the substrate 300, an example palladium layer 308 coupled to a second example surface 310 of the nickel layer 306, and an example gold layer 312 coupled to a third example surface 314 of the palladium layer 308. In some examples, the surface finish layers 302 are in direct contact with one another and the substrate 300 without intermediate layers (e.g., adhesives) disposed therebetween. That is, in some examples, the gold layer 312 is in direct contact with the palladium layer, which is in direct contacts with the nickel layer 306, which is in direct contact with the substrate 300. In some examples, a different material may be used for one or more of the surface finish layers 302. In some examples, one or more of the surface finish layers 302 may be omitted. In some examples, one or more additional layers may be included in the surface finish layers 302 shown in FIG. 3, and/or an arrangement of the surface finish layers 302 may be different from that shown in FIG. 3.

In some examples, the surface finish layers 302 are provided on the substrate 300 using electrolytic plating (e.g., using electricity). In some examples, electrolytic plating is used when electroless plating (e.g., using a shock and sway technique) is not compatible with the underlying substrate 300. For example, a shock and sway technique may not be effective and/or feasible when the substrate 300 includes the glass core 120 of FIG. 1.

In some examples, an example adhesive layer (e.g., an adhesion promoter) 316 is used to couple the example solder resist 318 to the surface finish layers 302. In some examples, the adhesive layer 316 is used instead of direct bonding as described above in connection with FIG. 2. In some examples, the adhesive layer 316 improves reliability of bonding between the solder resist 318 and the surface finish layers 302 compared to direct bonding. In this example, the adhesive layer 316 includes silicon nitride (Si₃N₄). In some examples, one or more different materials may be used for the adhesive layer 316 instead. In some examples, the adhesive layer 316 is coupled to (e.g., provided on) a fourth example surface 320 of the gold layer 312 by depositing and/or sputtering silicon nitride on the fourth surface 320, and the solder resist 318 is coupled to (e.g., provided on) a fifth example surface 322 of the adhesive layer 316. In some examples, heat and/or pressure is applied to the substrate 300 and/or the solder resist 318 to facilitate bonding between the solder resist 318 and the surface finish layers 302 at the adhesive layer 316.

As described above in connection with FIG. 2, an example aqueous developer (e.g., including sodium carbonate and/or magnesium sulfate) can be provided to a sixth example surface (e.g., an outer surface) 324 of the solder resist 318 to dissolve and/or remove portions of the solder resist 318 corresponding to a pattern. In some examples, the pattern is provided on the sixth surface 324 of the solder resist 318 by directing light toward portions of the sixth surface 324. In some examples, the pattern corresponds to locations of conductive traces and/or pads on the substrate 300. As a result of exposure of the solder resist 318 to the aqueous developer, a first example opening 326 is formed between the sixth surface 324 of the solder resist 318 and the fifth surface 322 of the adhesive layer 316. In the illustrated example, the first opening 326 includes an example undercut 328. In other words, a width of the first opening 326 decreases from the sixth surface 324 to an example point 330 between the fifth and sixth surfaces 322, 324, and the width of the first opening 326 increases from the point 330 to the fifth surface 322. Stated differently, the undercut 328 defines a gap between the fifth surface 322 of the adhesive layer and an overhang defined near the base of the sidewall of the first opening 326. In other words, the undercut 328 defines a portion of the solder resist with a surface that faces toward the underlying adhesive layer 316 while being spaced apart from the adhesive layer 316. Although the point 330 is shown as a discrete inflection point along the first opening 326, in some examples, the transition along the first opening 326 between the fifth and sixth surfaces 322, 324 is not discrete, but may be gradual and/or characterized by a curve.

In some examples, one or more portions of the adhesive layer 316 can be removed to reveal and/or expose the underlying surface finish layers 302 (e.g., the gold layer 312 at the top of the surface finish layers 302 in FIG. 3) and, thus, enable electrical connections between devices to be coupled to the substrate 300. For example, the one or more portions of the adhesive layer 316 can be removed by dry etching (e.g., plasma etching) in which plasma is directed at the adhesive layer 316. However, use of the aqueous developer to develop the first opening 326 may result in example sodium ions 332 and/or example magnesium ions 334 remaining on the fifth surface 322 of the gold layer 312 and/or the sixth surface 324 of the solder resist 318 after development. In some examples, the ions 332, 334 may inhibit the effectiveness of the dry etching (e.g., plasma etching) process on the underlying portions of the adhesive layer 316.

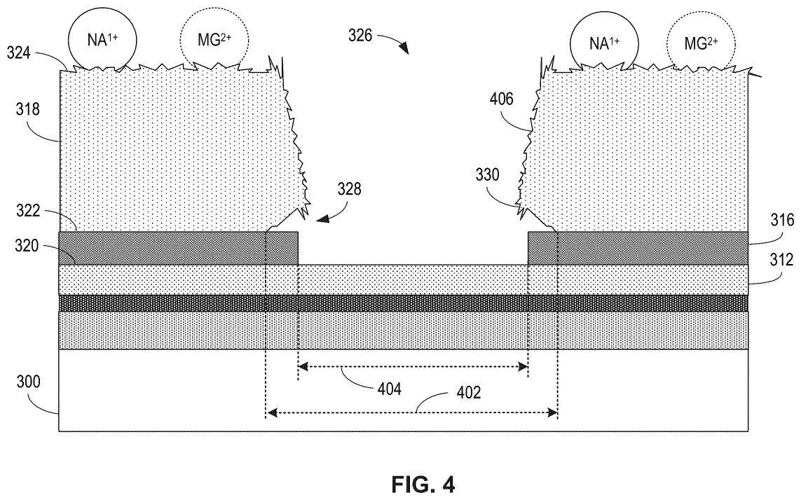

FIG. 4 illustrates the example substrate 300 and the example solder resist 318 of FIG. 3 after etching. In the illustrated example of FIG. 4, a portion of the adhesive layer 316 is removed such that the first opening 326 extends from the sixth surface 324 of the solder resist 318 to the fourth surface 320 of the gold layer 312. In some examples, the first opening 326 and the exposed portion of the gold layer 312 correspond to a location of and enable the fabrication of an interconnect between the substrate 300 and a separate interfacing substrate (e.g., the second electrical connections 114 between the dies 106, 108 and the package substrate 110 and/or the first electrical connections 104 between the package substrate 110 and the PCB 102). In some examples, the portion of the adhesive layer 316 is removed using a dry etching process in which plasma is directed at the adhesive layer 316 until the underlying gold layer 312 is revealed. For example, the plasma can include fluorinated gas which reacts with the silicon nitride of the adhesive layer 316 to break down molecules of the adhesive layer 316. While the plasma includes fluorine in this example, one or more different gases and/or chemicals may be used to perform the etching instead.

In some examples, a width of a plasma beam used for etching the adhesive layer 316 is restricted as a result of the undercut 328 included in the cross-sectional profile of the first opening 326. For example, a portion of the adhesive layer 316 below the undercut 328 is covered by the solder resist 318, such that plasma is less likely to reach the portion of the adhesive layer 316 during etching. In some examples, the width of the plasma beam that reaches the adhesive layer 316 is limited to be less than or equal to the width of the first opening 326 at the point 330, at which the width of the first opening 326 is smaller than at any other point along the first opening 326. In some examples, because the width of the plasma beam is restricted, the corresponding size of the first opening 326 extending through the adhesive layer 316 is also restricted. As illustrated in FIG. 4, a first width 402 of the first opening 326 at the adhesive layer 316 is less than a second width 404 of the first opening 326 at the solder resist 318 proximate the adhesive layer 316. As a result, a portion of the adhesive layer 213 below the undercut 328 in FIG. 4 is exposed (e.g., is not coated by the solder resist 318).

In the illustrated example of FIG. 4, the sixth surface 324 of the solder resist 318 and example sidewalls 406 of the first opening 326 include a roughened surface texture that has been exaggerated for purposes of explanation. In some examples, the roughened surface texture results from the use of the aqueous developer (e.g., including sodium carbonate and/or magnesium sulfate) to produce the first opening 326 in combination with the dry etching (e.g., plasma etching) of the adhesive layer 316. Specifically, as discussed above, application of the aqueous developer can leave trace ions 332, 334 that act as a mask to block the plasma etching from evenly interacting with the exposed surfaces of the solder resist 318, thereby resulting in the roughened surface. In some examples, the sixth surface 324 and/or the sidewalls 406 have a relatively rough surface (e.g., having a surface roughness greater than 120 nanometers). In some examples, the portion of the sidewalls below the point 330 corresponding to the surface of the undercut 328 is less roughened because the plasma etch does not act on that surface. In some examples, the roughened surface texture of the solder resist 318 may reduce reliability of the solder resist 318 during subsequent assembly procedures.

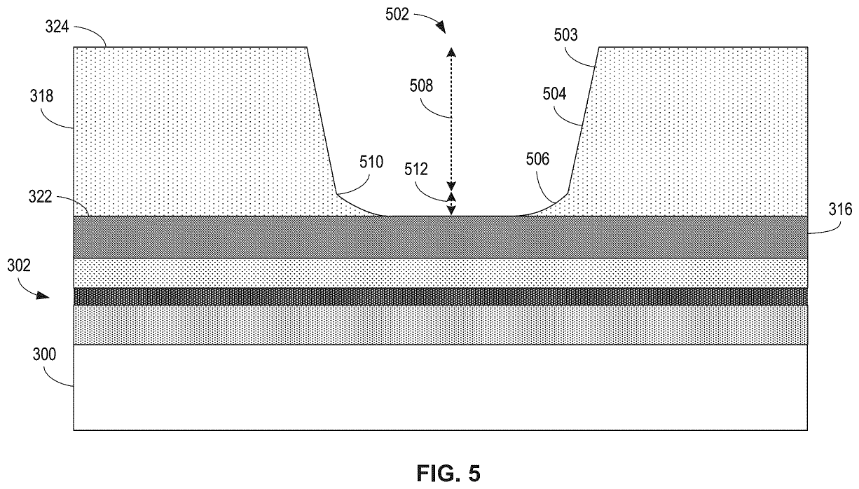

FIG. 5 illustrates the example solder resist 318 including a second example opening 502 instead of the first opening 326 of FIGS. 3 and/or 4. In the illustrated example of FIG. 5, the second opening 502 is produced when the patterned solder resist 318 is exposed to a TMAH developer (e.g., a TMAH developer) instead of the aqueous developer described above in connection with FIGS. 2, 3, and/or 4. In this example, after patterning of the solder resist 318, the TMAH developer is provided to the sixth surface 324 of the solder resist 318. In some examples, the TMAH developer includes at least carbon, hydrogen, nitrogen, and oxygen. In some examples, the TMAH developer reacts with the solder resist 318 to produce the second opening 502, and the solder resist 318 is rinsed with deionized water to remove the TMAH developer from one or more surfaces (e.g., the sixth surface 324 and the second opening 502) of the solder resist 318.

In some examples, the TMAH development process (e.g., applying TMAH developer to the solder resist 318 and rinsing with deionized water) occurs more gradually (e.g., over a longer duration) compared to an aqueous development process (e.g., quenching with sodium carbonate and rising with magnesium sulfate) described above in connection with FIGS. 2-4. As a result, the TMAH development process results in the second opening 502 having a different cross-sectional shape than the first opening 326 of FIGS. 3 and/or 4 produced using the aqueous development process. In particular, the second opening 502 of FIG. 5 has a tapered cross-sectional shape and does not include the undercut 328 of FIGS. 3 and/or 4. That is, there is no overhang on an example sidewall 503 of the second opening 502 and, therefore, there is no gap between the fifth surface 322 of the adhesive layer 316 and a surface of the solder resist 318 that faces toward the underlying adhesive layer 316 but is spaced apart from the adhesive layer 316. Stated differently, a width of the second opening 502 decreases from the sixth surface 324 (e.g., the top) of the solder resist 318 to the fifth surface 322 of the adhesive layer 316 (e.g., the bottom of the solder resist 318). In some examples, as a result of not including the undercut 328, the second opening 502 reduces a likelihood of flux trapping compared to the first opening 326 of FIGS. 3 and/or 4.

In the illustrated example of FIG. 5, a width of the second opening 502 decreases from the sixth surface 324 of the solder resist 318 to the fifth surface 322 of the adhesive layer 316. In this example, the second opening 502 includes the sidewall 503 defined by an example main region (e.g., a sloped region) 504 and an example footer region 506. In the illustrated example, the main region 504 is proximate (e.g., adjacent) the sixth surface 324 of the solder resist 318, and the footer region 506 is proximate (e.g., adjacent) the fifth surface 322 of the adhesive layer 316 (e.g., at a bottom or base of the second opening 502). In this example, the width of the second opening 502 decreases at a first rate along a first example length (e.g., a first thickness) 508 of the main region 504 from the sixth surface 324 to an example point 510 between the main and footer regions 504, 506. Further, the width of the second opening 502 decreases at a second rate along a second example length (e.g., second thickness) 512 of the footer region 605 from the point 510 to the fifth surface 522, where the second rate is greater than the first rate. As shown in the illustrated example, the main region 504 of the sidewall 503 corresponds to a majority of a thickness of the solder resist 318 (e.g., the first length 508 is greater than the second length 512). Although the point 510 is shown as a discrete inflection point along the sidewall of the second opening 502, in some examples, the transition between the upper sidewall region 504 and the lower footer region 605 is not discrete, but may be gradual and/or characterized by a curve. Likewise, in some examples, the rate at which the width of the second opening 502 changes along the depth of the opening (e.g., the angle or slope of the opening sidewall) is not necessarily constant in either the main region 504 or the footer region 506. However, in some examples, there is greater variability in the rate at which the width of the opening 502 changes in the footer region 506 than in the main region 504. In some examples, the width of the second opening 502 changes at a substantially constant rate along the first length 508, and changes at a variable rate (e.g., an exponential rate) along the second length 512. In some examples, the width of the second opening 502 is smaller at a location of the footer region 506 adjacent the adhesive layer 516 than at any other depth along the sidewall 503 of second opening 502.

In some examples, while the aqueous development process of FIGS. 3 and/or 4 leaves trace ions (e.g., sodium ions 332 and/or magnesium ions 334) on the solder resist 318 and/or the adhesive layer 316, the TMAH development process results in little to no trace ions being left on the solder resist 318 and/or the adhesive layer 316. Because the TMAH development process produces little to no trace ions, no ion mask is generated on the solder resist 318 and/or the adhesive layer 316 to prevent and/or restrict etching thereof. Accordingly, in some examples, surfaces of the solder resist 318 and/or the adhesive layer 316 are smoother (e.g., have a lower surface roughness) when the TMAH development process is used (followed by the plasma etching discussed above) compared to when the aqueous development process is used. For example, the surface roughness of the solder resist 318 can be less than 120 nanometers.

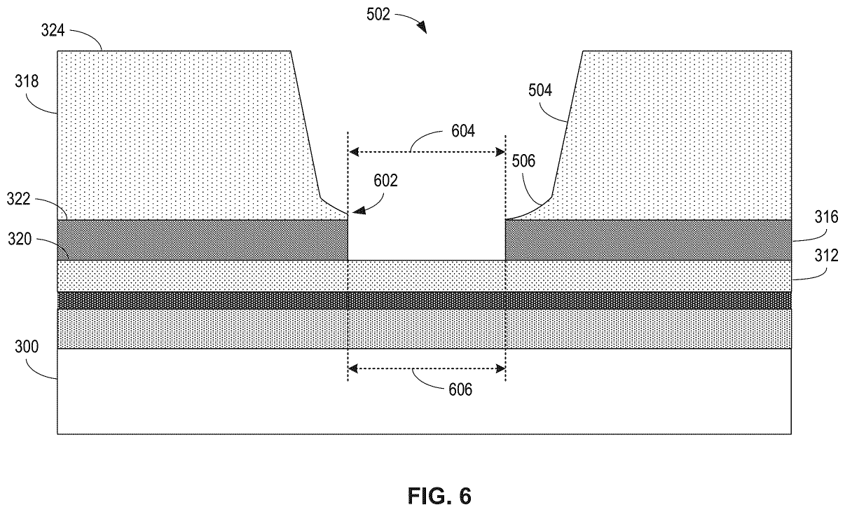

FIG. 6 illustrates the solder resist 318 including the second example opening 502 of FIG. 5 after etching. In the illustrated example of FIG. 6, dry etching (e.g., plasma etching) is used to remove a portion of the adhesive layer 316 corresponding to the second opening 502. In some examples, the solder resist 318 retains a relatively smooth surface (e.g., having a surface roughness less than 120 nanometers, less than 100 nanometers, less than 50 nanometers, etc.) after dry etching of the adhesive layer 316. In some examples, as a result of the etching, the second opening 502 extends from the sixth surface 324 of the solder resist 318 to the fourth surface 320 of the gold layer 312 to reveal and/or expose the gold layer 312. In some examples, the second opening 502 and the exposed portion of the gold layer 312 correspond to a location of and enable the fabrication of an interconnect between the substrate 300 and a separate interfacing substrate (e.g., the second electrical connections 114 between the dies 106, 108 and the package substrate 110 and/or the first electrical connections 104 between the package substrate 110 and the PCB 102).

In some examples, example ends 602 of the footer region 506 are removed along with the portion of the adhesive layer 316 during etching. In some examples, the width of the second opening 502 decreases from the sixth surface 324 to the ends 602 of the footer region 506, and the width of the second opening 502 is substantially constant (e.g., not changing, changing less than 1%) between the ends 602 and the gold layer 312. In particular, a first width 604 of the second opening 502 at a point on the solder resist 318 adjacent the adhesive layer 316 corresponds to (e.g., is substantially equal to) a second width 606 of the second opening 502 within the adhesive layer 316. In some examples, the width of the second opening 502 at the adhesive layer 316 and/or at the ends 602 of the footer region 506 is less than the width of the second opening 502 along other points (e.g., any other point) between the sixth surface 324 and the ends 602.

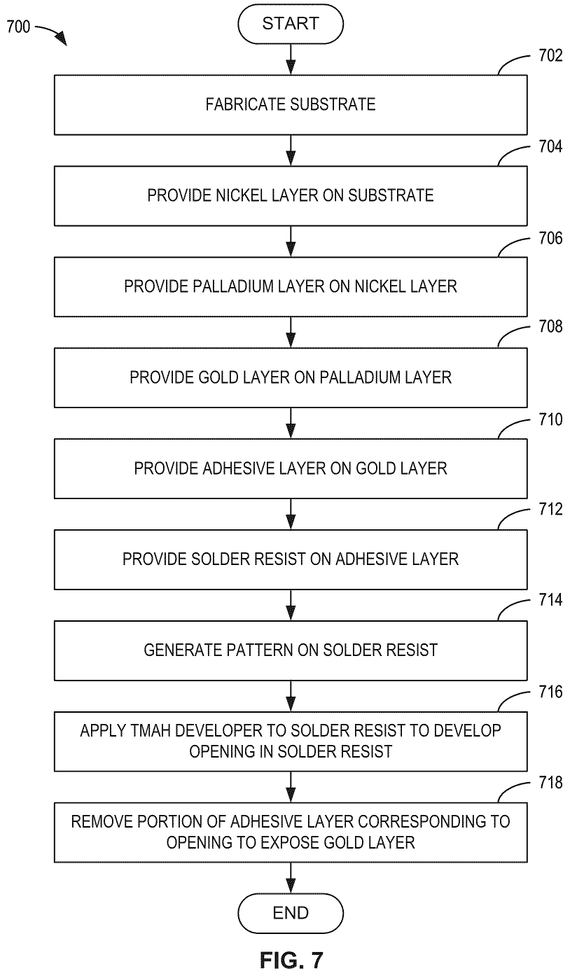

FIG. 7 is a flowchart representative of an example method 700 of manufacturing the example substrate 300 including the example solder resist 318 having the second example opening 502 of FIGS. 5 and/or 6. In some examples, some or all of the operations outlined in the example method 700 are performed automatically by fabrication equipment that is programmed to perform the operations. Although the example method of manufacturing is described with reference to the flowchart illustrated in FIG. 7, many other methods may alternatively be used. For example, the order or execution of the blocks may be changed, and/or some of the blocks described may be combined, divided, re-arranged, omitted, eliminated, and/or implemented in any other way.

The example method 700 begins at block 702 by fabricating the example substrate 300 of FIGS. 5 and/or 6. In some examples, the substrate 300 includes metal (e.g., copper). In some examples, the substrate 300 includes and/or is couplable to a glass core. For example, the substrate 300 can be fabricated by providing (e.g., depositing) layers of material (e.g., metal, build-up layers) on the glass core.

At block 704, the example method 700 includes providing the example nickel layer 306 on the substrate 300. For example, the nickel layer 306 is provided on the first surface 304 of the substrate 300. In some examples, the nickel layer 306 is provided by laminating and/or depositing layers of nickel material on the first surface 304 of the substrate 300.

At block 706, the example method 700 includes providing the example palladium layer 308 on the nickel layer 306. For example, the palladium layer 308 is provided on the second surface 310 of the nickel layer 306. In some examples, the palladium layer 308 is provided by laminating and/or depositing palladium material on the second surface 310 of the nickel layer 306.

At block 708, the example method 700 includes providing the example gold layer 312 on the palladium layer 308. For example, the gold layer 312 is provided on the third surface 314 of the palladium layer 308. In some examples, the gold layer 312 is provided by laminating and/or depositing gold material on the third surface 314 of the palladium layer 308.

At block 710, the example method 700 includes providing the example adhesive layer 316 on the gold layer 312. For example, the adhesive layer 316 is provided on the fourth surface 320 of the gold layer 312. In some examples, the adhesive layer 316 includes silicon nitride. In some examples, the adhesive layer 316 is provided by depositing and/or sputtering the silicon nitride on the fourth surface 320 of the gold layer 312.

At block 712, the example method 700 includes providing the example solder resist 318 on the adhesive layer 316. For example, the solder resist 318 is provided on the fifth surface 322 of the adhesive layer 316. In some examples, the solder resist 318 is laminated and/or deposited on the fifth surface 322 of the adhesive layer 316.

At block 714, the example method 700 includes generating an example pattern on the example solder resist 318. In some examples, the pattern is provided on the sixth surface 324 of the solder resist 318 using photolithography. For example, a mask corresponding to the pattern is provided on and/or proximate the sixth surface 324. In some examples, light is emitted toward the sixth surface 324, and the mask enables the light to pass to one or more first areas of the sixth surface 324, and the mask blocks and/or restricts light from one or more second areas of the sixth surface 324. In such examples, the first areas and/or the second areas correspond to the pattern.

At block 716, the example method 700 includes applying a TMAH developer to the solder resist 318 to develop the second example opening 502 in the solder resist 318. For example, the TMAH developer is applied to the sixth surface 324 of the solder resist 318 to dissolve and/or remove the first areas or the second areas of the solder resist 318 corresponding to the pattern. In some examples, the second opening 502 is produced as a result of the dissolving by the TMAH developer. In some examples, the second opening 502 extends through the solder resist 318 between the sixth surface 324 of the solder resist 318 and the fifth surface 322 of the adhesive layer 316. In some examples, the second opening 502 has a tapered cross-sectional shape having a width that decreases from the sixth surface 324 to the fifth surface 322.

At block 718, the example method 700 includes removing a portion of the adhesive layer 316 corresponding to the second opening 502 to expose the gold layer 312. In some examples, dry etching (e.g., plasma etching) is used to remove the portion of the adhesive layer 316. For example, plasma is directed to the fifth surface 322 of the adhesive layer 316 to etch the adhesive layer 316 until at least the fourth surface 320 of the gold layer 312 is exposed.

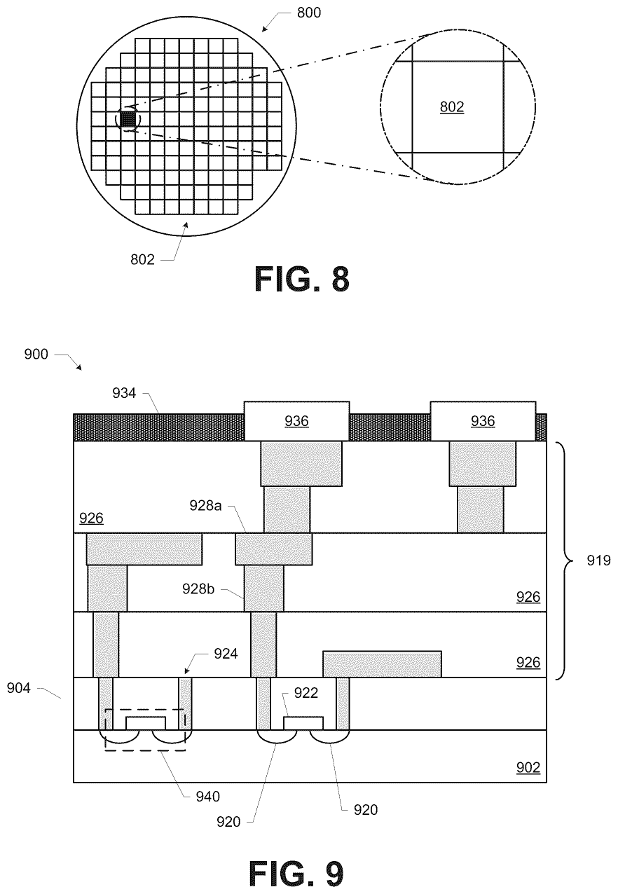

The example adhesive layer 316 disclosed herein may be included in any suitable electronic component. FIGS. 8-12 illustrate various examples of apparatus that may include the example adhesive layer 316 disclosed herein.

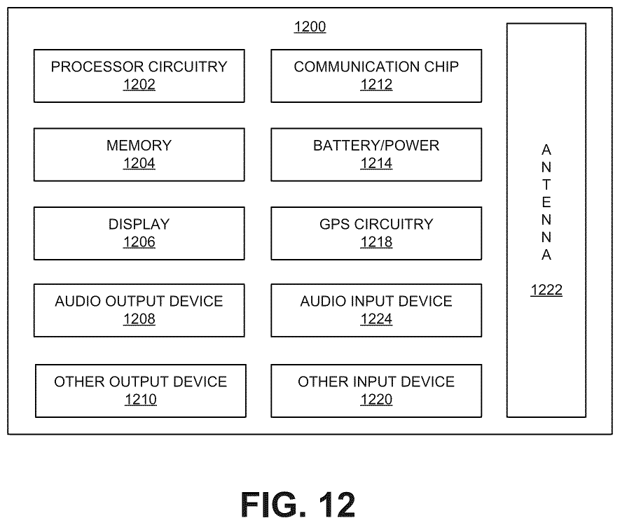

FIG. 8 is a top view of a wafer 800 and dies 802 that may be included in an IC package including the adhesive layer 316 in accordance with any of the examples disclosed herein. The wafer 800 may be composed of semiconductor material and may include one or more dies 802 having circuitry. Each of the dies 802 may be a repeating unit of a semiconductor product. After the fabrication of the semiconductor product is complete, the wafer 800 may undergo a singulation process in which the dies 802 are separated from one another to provide discrete “chips.” The die 802 may include one or more transistors (e.g., some of the transistors 940 of FIG. 9, discussed below), supporting circuitry to route electrical signals to the transistors, passive components (e.g., traces, resistors, capacitors, inductors, and/or other circuitry), and/or any other components. In some examples, the die 802 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 802. For example, a memory array formed by multiple memory circuits may be formed on a same die 802 as programmable circuitry (e.g., the processor circuitry 1202 of FIG. 12) or other logic circuitry. Such memory circuitry may store information or instructions for use by the programmable circuitry. The example IC package 100 disclosed herein may be manufactured using a die-to-wafer assembly technique in which some dies are attached to a wafer 800 that include others of the dies, and the wafer 800 is subsequently singulated.

FIG. 9 is a cross-sectional side view of an IC device 900 that may be included in an IC package including the adhesive layer 316, in accordance with any of the examples disclosed herein. One or more of the IC devices 900 may be included in one or more dies 802 (FIG. 8). The IC device 900 may be formed on a die substrate 902 (e.g., the wafer 800 of FIG. 8) and may be included in a die (e.g., the die 802 of FIG. 8). The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some examples, the die substrate 902 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an IC device 900 may be used. The die substrate 902 may be part of a singulated die (e.g., the dies 802 of FIG. 8) or a wafer (e.g., the wafer 800 of FIG. 8).

The IC device 900 may include one or more device layers 904 disposed on or above the die substrate 902. The device layer 904 may include features of one or more transistors 940 (e.g., metal oxide semiconductor field-effect transistors (MOSFETs)) formed on the die substrate 902. The device layer 904 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 940 may include a gate 922 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 940 along the source-channel-drain direction, the gate electrode may consist of a U-shaped structure that includes a bottom portion substantially parallel to the surface of the die substrate 902 and two sidewall portions that are substantially perpendicular to the top surface of the die substrate 902. In other examples, at least one of the metal layers that form the gate electrode may simply be a planar layer that is substantially parallel to the top surface of the die substrate 902 and does not include sidewall portions substantially perpendicular to the top surface of the die substrate 902. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of each transistor 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 920 may be formed using one or more alternate semiconductor materials such as germanium or a group III-V material or alloy. In further examples, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the IC device 900.

The interconnect structures 928 may be arranged within the interconnect layers 906-910 to route electrical signals according to a wide variety of designs (in particular, the arrangement is not limited to the particular configuration of interconnect structures 928 depicted in FIG. 9). Although a particular number of interconnect layers 906-910 is depicted in FIG. 9, examples of the present disclosure include IC devices having more or fewer interconnect layers than depicted.

In some examples, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page from the perspective of FIG. 9. The vias 928b may be arranged to route electrical signals in a direction of a plane that is substantially perpendicular to the surface of the die substrate 902 upon which the device layer 904 is formed. In some examples, the vias 928b may electrically couple lines 928a of different interconnect layers 906-910 together.

The interconnect layers 906-910 may include a dielectric material 926 disposed between the interconnect structures 928, as shown in FIG. 9. In some examples, the dielectric material 926 disposed between the interconnect structures 928 in different ones of the interconnect layers 906-910 may have different compositions; in other examples, the composition of the dielectric material 926 between different interconnect layers 906-910 may be the same.

A first interconnect layer 906 (referred to as Metal 1 or “M1”) may be formed directly on the device layer 904. In some examples, the first interconnect layer 906 may include lines 928a and/or vias 928b, as shown. The lines 928a of the first interconnect layer 906 may be coupled with contacts (e.g., the S/D contacts 924) of the device layer 904.

A second interconnect layer 908 (referred to as Metal 2 or “M2”) may be formed directly on the first interconnect layer 906. In some examples, the second interconnect layer 908 may include vias 928b to couple the lines 928a of the second interconnect layer 908 with the lines 928a of the first interconnect layer 906. Although the lines 928a and the vias 928b are structurally delineated with a line within each interconnect layer (e.g., within the second interconnect layer 908) for the sake of clarity, the lines 928a and the vias 928b may be structurally and/or materially contiguous (e.g., simultaneously filled during a dual-damascene process) in some examples.

A third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some examples, the interconnect layers that are “higher up” in the metallization stack 919 in the IC device 900 (i.e., further away from the device layer 904) may be thicker.

The IC device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to other external devices. For example, solder bonds may be formed on the one or more conductive contacts 936 to mechanically and/or electrically couple a chip including the IC device 900 with another component (e.g., a circuit board). The IC device 900 may include additional or alternate structures to route the electrical signals from the interconnect layers 906-910; for example, the conductive contacts 936 may include other analogous features (e.g., posts) that route the electrical signals to external components.

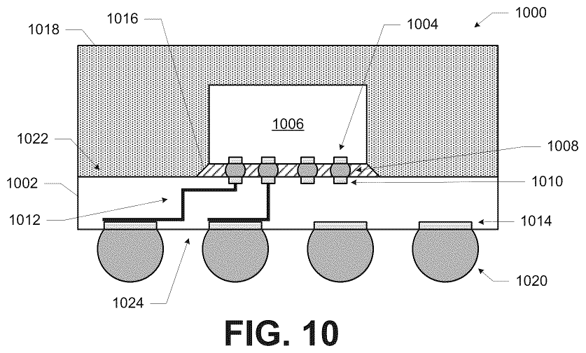

FIG. 10 is a cross-sectional view of an example IC package 1000 that may include the adhesive layer 316. The package substrate 1002 may be formed of a dielectric material, and may have conductive pathways extending through the dielectric material between upper and lower faces 1022, 1024, or between different locations on the upper face 1022, and/or between different locations on the lower face 1024. These conductive pathways may take the form of any of the interconnects 928 discussed above with reference to FIG. 9. In some examples, any number of the adhesive layer 316 (with any suitable structure) may be included in a package substrate 1002. In some examples, no adhesive layer 316 may be included in the package substrate 1002.

The IC package 1000 may include a die 1006 coupled to the package substrate 1002 via conductive contacts 1004 of the die 1006, first-level interconnects 1008, and conductive contacts 1010 of the package substrate 1002. The conductive contacts 1010 may be coupled to conductive pathways 1012 through the package substrate 1002, allowing circuitry within the die 1006 to electrically couple to various ones of the conductive contacts 1014 (or to other devices included in the package substrate 1002, not shown). The first-level interconnects 1008 illustrated in FIG. 10 are solder bumps, but any suitable first-level interconnects 1008 may be used. As used herein, a “conductive contact” refers to a portion of conductive material (e.g., metal) serving as an electrical interface between different components. Conductive contacts may be recessed in, flush with, or extending away from a surface of a component, and may take any suitable form (e.g., a conductive pad or socket).

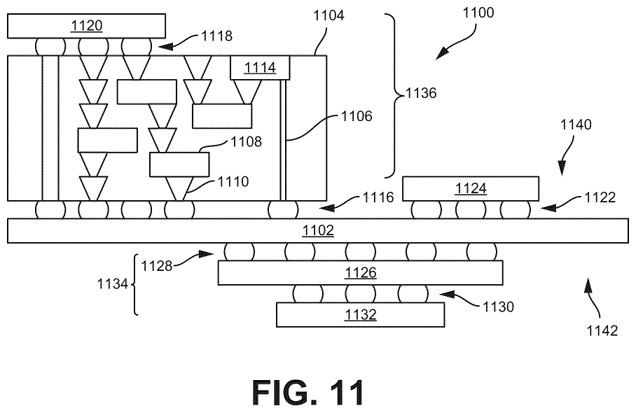

In some examples, an underfill material 1016 may be disposed between the die 1006 and the package substrate 1002 around the first-level interconnects 1008, and a mold compound 1018 may be disposed around the die 1006 and in contact with the package substrate 1002. In some examples, the underfill material 1016 may be the same as the mold compound 1018. Example materials that may be used for the underfill material 1016 and the mold compound 1018 are epoxy mold materials, as suitable. Second-level interconnects 1020 may be coupled to the conductive contacts 1014. The second-level interconnects 1020 illustrated in FIG. 10 are solder balls (e.g., for a ball grid array arrangement), but any suitable second-level interconnects 1020 may be used (e.g., pins in a pin grid array arrangement or lands in a land grid array arrangement). The second-level interconnects 1020 may be used to couple the IC package 1000 to another component, such as a circuit board (e.g., a motherboard), an interposer, or another IC package, as known in the art and as discussed below with reference to FIG. 11.

In FIG. 10, the IC package 1000 is a flip chip package, and includes an adhesive layer 316 coupled to the package substrate 1002. The number and location of the adhesive layer 316 of the IC package 1000 is simply illustrative, and any number of the adhesive layer 316 (with any suitable structure) may be coupled to a package substrate 1002. In some examples, no adhesive layer 316 may be coupled to the package substrate 1002. The die 1006 may take the form of any of the examples of the die 1202 discussed herein (e.g., may include any of the examples of the IC device 900).

Although the IC package 1000 illustrated in FIG. 10 is a flip chip package, other package architectures may be used. For example, the IC package 1000 may be a ball grid array (BGA) package, such as an embedded wafer-level ball grid array (eWLB) package. In another example, the IC package 1000 may be a wafer-level chip scale package (WLCSP) or a panel fanout (FO) package. Although a single die 1006 is illustrated in the IC package 1000 of FIG. 10, an IC package 1000 may include multiple dies 1006. An IC package 1000 may include additional passive components, such as surface-mount resistors, capacitors, and inductors disposed on the first face 1022 or the second face 1024 of the package substrate 1002. More generally, an IC package 1000 may include any other active or passive components known in the art.

FIG. 11 is a cross-sectional side view of an IC device assembly 1100 that may include the adhesive layer 316 disclosed herein. The IC device assembly 1100 includes a number of components disposed on a circuit board 1102 (which may be, for example, a motherboard). The IC device assembly 1100 includes components disposed on a first face 1140 of the circuit board 1102 and an opposing second face 1142 of the circuit board 1102. Generally, components may be disposed on one or both faces 1140 and 1142.

In some examples, the circuit board 1102 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1102. In other examples, the circuit board 1102 may be a non-PCB substrate.

The IC device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), male and female portions of a socket, an adhesive, an underfill material, and/or any other suitable electrical and/or mechanical coupling structure.

The package-on-interposer structure 1136 may include an IC package 1120 coupled to an interposer 1104 by coupling components 1118. The coupling components 1118 may take any suitable form for the application, such as the forms discussed above with reference to the coupling components 1116. Although a single IC package 1120 is shown in FIG. 11, multiple IC packages may be coupled to the interposer 1104; indeed, additional interposers may be coupled to the interposer 1104. The interposer 1104 may provide an intervening substrate used to bridge the circuit board 1102 and the IC package 1120. The IC package 1120 may be or include, for example, a die (the die 802 of FIG. 8), an IC device (e.g., the IC device 900 of FIG. 9), or any other suitable component. Generally, the interposer 1104 may spread a connection to a wider pitch or reroute a connection to a different connection. For example, the interposer 1104 may couple the IC package 1120 (e.g., a die) to a set of BGA conductive contacts of the coupling components 1116 for coupling to the circuit board 1102. In the example illustrated in FIG. 11, the IC package 1120 and the circuit board 1102 are attached to opposing sides of the interposer 1104; in other examples, the IC package 1120 and the circuit board 1102 may be attached to a same side of the interposer 1104. In some examples, three or more components may be interconnected by way of the interposer 1104.

In some examples, the interposer 1104 may be formed as a PCB, including multiple metal layers separated from one another by layers of dielectric material and interconnected by electrically conductive vias. In some examples, the interposer 1104 may be formed of an epoxy resin, a fiberglass-reinforced epoxy resin, an epoxy resin with inorganic fillers, a ceramic material, or a polymer material such as polyimide. In some examples, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through-silicon vias (TSVs) 1106. The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The IC device assembly 1100 may include an IC package 1124 coupled to the first face 1140 of the circuit board 1102 by coupling components 1122. The coupling components 1122 may take the form of any of the examples discussed above with reference to the coupling components 1116, and the IC package 1124 may take the form of any of the examples discussed above with reference to the IC package 1120.

The IC device assembly 1100 illustrated in FIG. 11 includes a package-on-package structure 1134 coupled to the second face 1142 of the circuit board 1102 by coupling components 1128. The package-on-package structure 1134 may include a first IC package 1126 and a second IC package 1132 coupled together by coupling components 1130 such that the first IC package 1126 is disposed between the circuit board 1102 and the second IC package 1132. The coupling components 1128, 1130 may take the form of any of the examples of the coupling components 1116 discussed above, and the IC packages 1126, 1132 may take the form of any of the examples of the IC package 1120 discussed above. The package-on-package structure 1134 may be configured in accordance with any of the package-on-package structures known in the art.

FIG. 12 is a block diagram of an example electrical device 1200 that may include the example adhesive layer 316. For example, any suitable ones of the components of the electrical device 1200 may include one or more of the device assemblies 1100, IC devices 900, or dies 802 disclosed herein. A number of components are illustrated in FIG. 12 as included in the electrical device 1200, but any one or more of these components may be omitted or duplicated, as suitable for the application. In some examples, some or all of the components included in the electrical device 1200 may be attached to one or more motherboards. In some examples, some or all of these components are fabricated onto a single system-on-a-chip (SoC) die.

Additionally, in various examples, the electrical device 1200 may not include one or more of the components illustrated in FIG. 12, but the electrical device 1200 may include interface circuitry for coupling to the one or more components. For example, the electrical device 1200 may not include a display 1206, but may include display interface circuitry (e.g., a connector and driver circuitry) to which a display 1206 may be coupled. In another set of examples, the electrical device 1200 may not include an audio input device 1224 (e.g., microphone) or an audio output device 1208 (e.g., a speaker, a headset, earbuds, etc.), but may include audio input or output device interface circuitry (e.g., connectors and supporting circuitry) to which an audio input device 1224 or audio output device 1208 may be coupled.

The electrical device 1200 may include programmable circuitry 1202 (e.g., one or more processing devices). The programmable circuitry 1202 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1200 may include a memory 1204, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1204 may include memory that shares a die with the programmable circuitry 1202. This memory may be used as cache memory and may include embedded dynamic random access memory (eDRAM) or spin transfer torque magnetic random access memory (STT-MRAM).

In some examples, the electrical device 1200 may include a communication chip 1212 (e.g., one or more communication chips). For example, the communication chip 1212 may be configured for managing wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1212 may operate in accordance with other wireless protocols in other examples. The electrical device 1200 may include an antenna 1222 to facilitate wireless communications and/or to receive other wireless communications (such as AM or FM radio transmissions).

In some examples, the communication chip 1212 may manage wired communications, such as electrical, optical, or any other suitable communication protocols (e.g., the Ethernet). As noted above, the communication chip 1212 may include multiple communication chips. For instance, a first communication chip 1212 may be dedicated to shorter-range wireless communications such as Wi-Fi or Bluetooth, and a second communication chip 1212 may be dedicated to longer-range wireless communications such as global positioning system (GPS), EDGE, GPRS, CDMA, WiMAX, LTE, EV-DO, or others. In some examples, a first communication chip 1212 may be dedicated to wireless communications, and a second communication chip 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display 1206 (or corresponding interface circuitry, as discussed above). The display 1206 may include any visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any device that generates an audible indicator, such as speakers, headsets, or earbuds.

The electrical device 1200 may include an audio input device 1224 (or corresponding interface circuitry, as discussed above). The audio input device 1224 may include any device that generates a signal representative of a sound, such as microphones, microphone arrays, or digital instruments (e.g., instruments having a musical instrument digital interface (MIDI) output).

The electrical device 1200 may include a GPS circuitry 1218. The GPS circuitry 1218 may be in communication with a satellite-based system and may receive a location of the electrical device 1200, as known in the art.

The electrical device 1200 may include any other output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include any other input device 1220 (or corresponding interface circuitry, as discussed above). Examples of the other input device 1220 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1200 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

From the foregoing, it will be appreciated that example systems, methods, apparatus, and articles of manufacture have been disclosed that produce integrated circuit packages by coupling solder resist to a substrate using an adhesive layer (e.g., a silicon nitride adhesive layer). In examples disclosed herein, the adhesive layer includes silicon nitride material coupled to a surface finish layer (e.g., a metal layer) of the substrate, and the solder resist is coupled to the silicon nitride. By using silicon nitride to couple the solder resist to the substrate, examples disclosed herein can be used with electrolytic surface finishes on the substrate (e.g., in addition to or instead of electroless surface finishes which require a shock and sway plating technique incompatible with some IC packages). Further, examples disclosed herein utilize a Tetramethylammonium hydroxide (TMAH) developer to dissolve a portion of the solder resist and provide an example opening in the solder resist. By using a TMAH developer instead of some known aqueous developers (e.g., including sodium carbonate and magnesium sulfate), examples disclosed herein produce the opening having a tapered cross sectional shape and no undercut, thus reducing a likelihood of flux trapping in the opening. Additionally, use of the TMAH developer ensures a relatively smooth surface of the solder resist and reduces (e.g., prevents) formation of an ion mask after development of the opening, thus enabling the use of dry etching (e.g., plasma etching) techniques in subsequent assembly procedures. Advantageously, dry etching may provide improved manufacturing precision and/or control compared to other etching techniques (e.g., wet etching). Further, by reducing surface roughness of the solder resist, disclosed systems, methods, apparatus, and articles of manufacture improve the efficiency of using a computing device by improving reliability of the solder resist in subsequent assembly procedures of the IC package. Disclosed systems, methods, apparatus, and articles of manufacture are accordingly directed to one or more improvement(s) in the operation of a machine such as a computer or other electronic and/or mechanical device.

Example methods, systems, apparatus, and articles of manufacture to produce integrated circuit packages having silicon nitride adhesion promoters are disclosed herein. Further examples and combinations thereof include the following:

Example 1 includes an integrated circuit (IC) package, comprising a metal layer on a substrate, a layer on the metal layer, the layer including silicon and nitrogen, and solder resist on the layer.

Example 2 includes the IC package of example 1, further including an opening extending between a first surface of the solder resist and a second surface of the layer, a width of the opening to be smaller proximate the layer than at any other point between the first and second surfaces.

Example 3 includes the IC package of example 2, wherein the opening is to extend between the first surface of the solder resist and a third surface of the metal layer.

Example 4 includes the IC package of example 3, wherein the opening has a first width at the solder resist proximate the second surface and a second width at the layer between the second and third surfaces, the first width corresponding to the second width.

Example 5 includes the IC package of example 2, wherein the opening does not include an undercut.

Example 6 includes the IC package of example 2, wherein a sidewall of the opening includes a main region proximate the first surface and a footer region proximate the second surface, the width of the opening having a first rate of change along the main region and a second rate of change along the footer region, the second rate of change greater than the first rate of change.

Example 7 includes the IC package of example 1, wherein the metal layer includes a nickel layer on the substrate, a palladium layer on the nickel layer, and a gold layer on the palladium layer.

Example 8 includes the IC package of example 1, wherein a surface roughness of the solder resist is less than 120 nanometers.

Example 9 includes a substrate of an integrated circuit (IC) package, the substrate comprising a surface finish layer having a first surface, an adhesion promoter on the first surface, the adhesion promoter including silicon and nitrogen, and a solder mask on a second surface of the adhesion promoter.

Example 10 includes the substrate of example 9, further including an opening extending through the solder mask and through the adhesion promoter, the opening having a tapered cross-sectional shape.

Example 11 includes the substrate of example 10, wherein a width of the opening is substantially constant between the first and second surfaces, the width of the opening to increase from the second surface to a third surface of the solder mask, the third surface facing away from the adhesion promoter.

Example 12 includes the substrate of example 11, wherein the width of the opening increases by a first rate from the second surface to a point between the second and third surfaces, the width of the opening to increase by a second rate from the point to the third surface, the first rate greater than the second rate.

Example 13 includes the substrate of example 9, wherein the surface finish layer includes at least one of a nickel layer, a palladium layer, or a gold layer.

Example 14 includes the substrate of example 9, wherein a surface roughness of the solder mask is up to 120 nanometers.

Example 15 includes a method comprising coupling a metal layer to a substrate, coupling an adhesive layer on the metal layer, the adhesive layer including silicon and nitrogen, and coupling solder resist to the adhesive layer.

Example 16 includes the method of example 15, further including providing an opening in the solder resist, the opening extending between a first surface of the solder resist and a second surface of the adhesive layer, a width of the opening to decrease from the first surface to the second surface.

Example 17 includes the method of example 16, wherein a sidewall of the opening does not include an overhang defining a gap between a third surface of the solder resist and the second surface of the adhesive layer, the third surface facing the second surface.

Example 18 includes the method of example 16, wherein providing the opening includes generating a pattern on the first surface of the solder resist, and providing a developer to the first surface to remove material from the solder resist corresponding to the pattern.

Example 19 includes the method of example 18, wherein the developer includes tetramethylammonium hydroxide (TMAH).

Example 20 includes the method of example 18, wherein the developer does not include magnesium and does not include sodium.

Example 21 includes the method of example 16, further including removing a portion of the adhesive layer by dry etching.

Example 22 includes the method of example 21, wherein the dry etching includes providing fluorinated gas to the opening.

Example 23 includes the method of example 15, wherein coupling the metal layer to the substrate includes coupling a nickel layer to the substrate, coupling a palladium layer to the nickel layer, and coupling a gold layer to the palladium layer.

Example 24 includes the method of example 15, further including coupling the metal layer to the substrate by electrolytic plating.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1. An integrated circuit (IC) package, comprising:
a metal layer on a substrate;
a layer on the metal layer, the layer including silicon and nitrogen; and
solder resist on the layer.

2. The IC package of claim 1, further including an opening extending between a first surface of the solder resist and a second surface of the layer, a width of the opening to be smaller proximate the layer than at any other point between the first and second surfaces.

3. The IC package of claim 2, wherein the opening is to extend between the first surface of the solder resist and a third surface of the metal layer.

4. The IC package of claim 3, wherein the opening has a first width at the solder resist proximate the second surface and a second width at the layer between the second and third surfaces, the first width corresponding to the second width.

5. The IC package of claim 2, wherein the opening does not include an undercut.

6. The IC package of claim 2, wherein a sidewall of the opening includes a main region proximate the first surface and a footer region proximate the second surface, the width of the opening having a first rate of change along the main region and a second rate of change along the footer region, the second rate of change greater than the first rate of change.

7. The IC package of claim 1, wherein the metal layer includes a nickel layer on the substrate, a palladium layer on the nickel layer, and a gold layer on the palladium layer.

8. The IC package of claim 1, wherein a surface roughness of the solder resist is less than 120 nanometers.

9. A substrate of an integrated circuit (IC) package, the substrate comprising:
a surface finish layer having a first surface;
an adhesion promoter on the first surface, the adhesion promoter including silicon and nitrogen; and
a solder mask on a second surface of the adhesion promoter.

10. The substrate of claim 9, further including an opening extending through the solder mask and through the adhesion promoter, the opening having a tapered cross-sectional shape.

11. The substrate of claim 10, wherein a width of the opening is substantially constant between the first and second surfaces, the width of the opening to increase from the second surface to a third surface of the solder mask, the third surface facing away from the adhesion promoter.

12. The substrate of claim 11, wherein the width of the opening increases by a first rate from the second surface to a point between the second and third surfaces, the width of the opening to increase by a second rate from the point to the third surface, the first rate greater than the second rate.

13. The substrate of claim 9, wherein the surface finish layer includes at least one of a nickel layer, a palladium layer, or a gold layer.

14. (canceled)

15. A method comprising:
coupling a metal layer to a substrate;
coupling an adhesive layer on the metal layer, the adhesive layer including silicon and nitrogen; and
coupling solder resist to the adhesive layer.

16. The method of claim 15, further including providing an opening in the solder resist, the opening extending between a first surface of the solder resist and a second surface of the adhesive layer, a width of the opening to decrease from the first surface to the second surface.

17. The method of claim 16, wherein a sidewall of the opening does not include an overhang defining a gap between a third surface of the solder resist and the second surface of the adhesive layer, the third surface facing the second surface.

18. The method of claim 16, wherein providing the opening includes:
generating a pattern on the first surface of the solder resist; and
providing a developer to the first surface to remove material from the solder resist corresponding to the pattern.

19. The method of claim 18, wherein the developer includes tetramethylammonium hydroxide (TMAH).

20. The method of claim 18, wherein the developer does not include magnesium and does not include sodium.

21. The method of claim 16, further including removing a portion of the adhesive layer by dry etching.

22-24. (canceled)
